(19) United States
(12) Patent Application Publication
(10) Pub. No.: US 2007/0230146 A1
(43) Pub. Date: Oct. 4, 2007

(54) Printed-wiring board with built-in component, manufacturing method of printed-wiring board with built-in component, and electronic device

(76) Inventors: Daigo Suzuki, Yakohama-shi (JP); Jun Karasawa, Tokyo (JP); Hidenori Tanaka, Hachioji-shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/728,546

(22) Filed: Mar. 26, 2007

(30) Foreign Application Priority Data
Mar. 30, 2006 (JP) 2006-095178

(51) Int. Cl. H05K 7/00

(52) U.S. Cl. 361/760

(57) ABSTRACT

According to one embodiment, a printed-wiring board with a built-in component includes a first base material including a component mounting surface. A circuit component is mounted on the component mounting surface of the first base material. A stress relaxation material covers the circuit component. A second base material is stacked on the first base material by interposing, between the first base material and the second base material, an insulating layer covering the stress relaxation material.

### CROSS-REFERENCE TO RELATED APPLICATIONS

This application is based upon and claims the benefit of priority from Japanese Patent Application No. 2006-095178, filed Mar. 30, 2006, the entire contents of which are incorporated herein by reference.

### BACKGROUND

1. Field

One embodiment of the invention relates to a printed-wiring board with a built-in component used in an electronic circuit. Another embodiment of the invention relates to a manufacturing method of a printed-wiring board with a built-in component. Still another embodiment of the invention relates to an electronic device using a printed-wiring board with a built-in component.

2. Description of the Related Art

In small electronic devices such as a portable computer, mobile terminal, etc., a component mounting technique is used which mounts components on a substrate which allows high-density wiring and a substrate which is manufactured in consideration of reliability. As for such component mounting techniques intended for semiconductor components, a technique is known which mounts a semiconductor component (semiconductor integrated circuit element) such as a BGA (ball grid array) on a substrate, and seals the semiconductor component mounted on the substrate by a resin.

Conventionally, such component mounting techniques include a technique which forms in advance a concave portion for housing an IC (BGA component) in a core substrate, which serves as an armoring material (sealant), and providing a specific resin in the concave portion and housing the IC therein, so as to relieve stress generated due to the difference between the thermal expansion of the IC and that of the core substrate.

On the other hand, recently, a manufacturing method has been developed for practical use which manufactures a printed-wiring board including a plurality of layers to be used in an electronic circuit device. In this manufacturing method, the printed-wiring board with a built-in electronic component is manufactured by solder bonding a chip component such as a passive element to a conductive pattern (pad) formed on an inner-layer side pattern forming surface, and stacking an insulating material on the inner-layer side so as to cover the chip component with the insulating material (for example, refer to Japanese Patent Application KOKAI Publication No. 2002-246722).

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIG. 1 is an exemplary cross-sectional view of a printed-wiring board with a built-in component according to a first embodiment of the invention;

FIG. 2 is an exemplary cross-sectional view showing a first process of a manufacturing process of the printed-wiring board according to the first embodiment;

FIG. 3 is an exemplary cross-sectional view showing a second process of the manufacturing process of the printed-wiring board according to the first embodiment;

FIG. 4 is an exemplary cross-sectional view showing a third process of the manufacturing process of the printed-wiring board according to the first embodiment;

FIG. 5 is an exemplary cross-sectional view showing a fourth process of the manufacturing process of the printed-wiring board according to the first embodiment;

FIG. 6 is an exemplary cross-sectional view showing a fifth process of the manufacturing process of the printed-wiring board according to the first embodiment;

FIG. 7 is an exemplary cross-sectional view showing a first process of a manufacturing process of a printed-wiring board with a built-in component according to a second embodiment of the invention;

FIG. 8 is an exemplary cross-sectional view showing a second process of the manufacturing process of the printed-wiring board according to the second embodiment;

FIG. 9 is an exemplary cross-sectional view showing a third process of the manufacturing process of the printed-wiring board according to the second embodiment;

FIG. 10 is an exemplary cross-sectional view showing a fourth process of the manufacturing process of the printed-wiring board according to the second embodiment;

FIG. 11 is an exemplary cross-sectional view showing a fifth process of the manufacturing process of the printed-wiring board according to the second embodiment;

FIG. 12 is an exemplary cross-sectional view showing a first process of a manufacturing process of a printed-wiring board with a built-in component according to a third embodiment of the invention;

FIG. 13 is an exemplary cross-sectional view showing a second process of the manufacturing process of the printed-wiring board according to the third embodiment;

FIG. 14 is an exemplary cross-sectional view showing a third process of the manufacturing process of the printed-wiring board according to the third embodiment;

FIG. 15 is an exemplary cross-sectional view showing a fourth process of the manufacturing process of the printed-wiring board according to the third embodiment;

FIG. 16 is an exemplary cross-sectional view showing a fifth process of the manufacturing process of the printed-wiring board according to the third embodiment; and

FIG. 17 is an exemplary perspective view showing a structure of an electronic device according to an embodiment of the invention.

### DETAILED DESCRIPTION

Various embodiments according to the invention will be described hereinafter with reference to the accompanying drawings. In general, according to one embodiment of the invention, there is provided a printed-wiring board with a built-in component including: a first base material including a component mounting surface; a circuit component mounted on the component mounting surface of the first base material; a stress relaxation material covering the circuit component; and a second base material stacked on the first base material by interposing, between the first base material and the second base material, an insulating layer covering the stress relaxation material.

In each of the following embodiments of the invention, a chip component including a component body having a rectangular parallelepiped shape and a pair of terminals, such as a capacitor, a resistance element, etc., is used as an example of a built-in circuit component. However, the built-in circuit component is not limited to such chip components. For example, the built-in circuit component may be an active element which includes two or more terminals and a specific function.

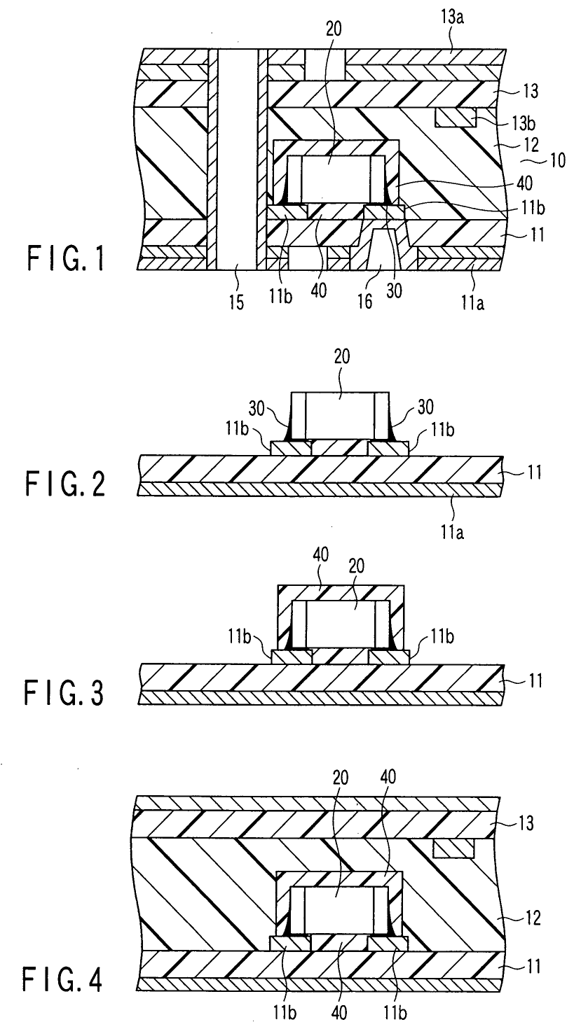

FIG. 1 shows an exemplary structure of a printed-wiring board 10 with a built-in component according to a first embodiment of the invention. The printed-wiring board 10 shown in FIG. 1 includes a first base material 11, a resin material 12 forming an insulating layer, and a second base material 13. The second base material 13, which serves as another member, is stacked on the first base material 11 by interposing the insulating layer 12 between the first base material 11 and the second base material 13.

Each of the first base material 11 and the second base material 13 is formed by using a sheet prepreg obtained by impregnating glass cloth with a resin. Each of the first base material 11 and the second base material 13 includes a pattern forming surface, which forms a conductive layer (wiring layer), on both sides (an outer-layer side and an inner-layer side) thereof. A conductive pattern 11a is formed on an outer-layer side pattern forming surface (wiring layer) of the first base material 11. A pair of electrodes 11b and 11b are formed on an inner-layer side pattern forming surface (wiring layer) of the first base material 11. The electrodes 11b and 11b are formed as a conductive pattern on a predetermined built-in component mounting portion of a component mounting surface. The electrodes 11b and 11b are solder bonded to terminals of the built-in component. A conductive pattern 13a is formed on an outer-layer side pattern forming surface (wiring layer) of the second base material 13. A conductive pattern 13b is formed on an inner-layer side pattern forming surface (wiring layer) of the second base material 13. In other words, each of the first base material 11 and the second base material 13 includes a plurality of wiring layers which form a multi-layer printed-wiring board.

The electrodes 11b and 11b, which are formed on the component mounting portion of the component mounting surface of the first base material 11, are solder bonded to terminals of a circuit component 20, which serves as the built-in component. In this manner, the circuit component 20 is mounted on the component mounting portion. The circuit component 20 includes a chip component including a component body. The component body is formed into a rectangular parallelepiped shape and is provided with a pair of electrodes (terminals).

The circuit component 20 is covered with a stress relaxation material 40 having a predetermined thickness, except for a bonding surface of a solder bonding portion 30. More specifically, the periphery (e.g., a top surface and side surfaces) of the circuit component 20 is covered with the stress relaxation material 40.

The stress relaxation material 40 serves to relax the stress due to expansion/contraction and the external stress on the circuit component 20. The stress relaxation material 40 is formed by, for example, a resin material having a thermal expansion coefficient between the thermal expansion of the resin material 12 and that of the circuit component 20, or a resin material having a thermal expansion coefficient which is lower than the thermal expansion coefficient of the resin material 12 and that of the circuit component 20. By using the resin material having the thermal expansion coefficient between the thermal expansion coefficient of the resin material 12 and that of the circuit component 20 (in other words, a thermo-setting resin material which relaxes a bending stress between the insulating layer and the circuit component 20), it is possible to expect a more effective relaxation effect against the external bending stress. Additionally, by using the resin material having the thermal expansion coefficient which is lower than the thermal expansion coefficient of the resin material 12 and that of the circuit component 20 (in other words, a thermo-setting resin material which relaxes a thermal stress between the insulating layer and the circuit component 20), it is possible to expect a more effective relaxation effect against the thermal stress from the outside.

As mentioned above, with the structure where the circuit component 20 covered with the stress relaxation material 40 is mounted in the printed-wiring board 10, even if the external stress or the stress due to thermal expansion is applied to the printed-wiring board 10 during a manufacturing process of the printed-wiring board 10, during a manufacturing process of a printed circuit board thereafter, or after mounting of the printed circuit board, it is possible to relax such stress by the stress relaxation material 40 and to protect the circuit component 20 from such stress. Further, since the space between the circuit component 20 and the component mounting surface of the first base material 11 is filled with the stress relaxation material 40, it is possible to prevent formation of voids under the circuit component 20. Accordingly, it is possible to provide a printed-wiring board with a built-in component with an improved reliability.

FIGS. 2 through 6 show an exemplary manufacturing process of the printed-wiring board 10 according to the first embodiment of the invention.

In a first process shown in FIG. 2, the electrodes 11b and 11b provided on the first base material 11 are solder bonded to terminals of the circuit component 20 by a solder 30. In this manner, the circuit component 20 is mounted on the component mounting surface of the first base material 11.

In a second process shown in FIG. 3, the circuit component 20 is covered with the stress relaxation material 40. The second process includes a process of filling, with the stress relaxation material 40, the space between the component mounting surface and a lower surface of the circuit component 20. For example, after filling the space with the stress relaxation material 40, the other portions of the circuit component 20 is covered with the stress relaxation material 40, and the stress relaxation material 40 is cured by performing a heating process thereon. In this manner, the stress relaxation material 40 having a predetermined thickness adheres to the circuit component 20.

In a third process shown in FIG. 4, the stress relaxation material 40 covering the circuit component 20 is covered with the resin material 12 so as to form an insulating layer on the first base material 11. Further, the second base material 13, which serves as another member, is stacked on the first base material 11 by interposing the insulating layer between the first base material and the second base material.

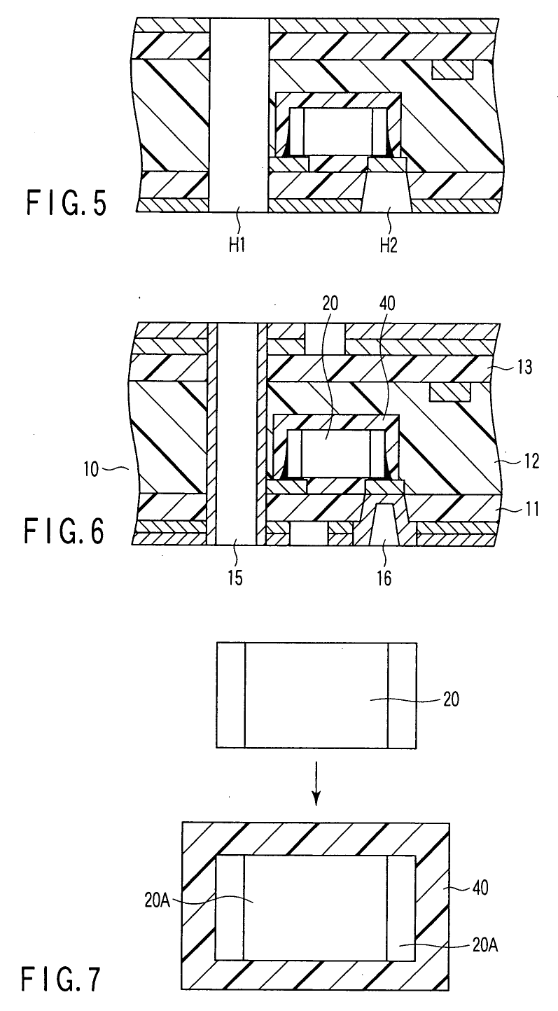

In a fourth process shown in FIG. 5, openings (holes) for forming a through-hole, a via hole, etc. are formed in the printed-wiring board 10 in which each of the above-mentioned members are integrated. The openings are formed by drilling or laser processing. The conductive patterns of the layers are electrically connected via the openings. The opening formed in the fourth process and serving as a through-hole is indicated by H1, and the opening formed in the fourth process and serving as a via hole is indicated by H2.

In a fifth process shown in FIG. 6, a through-hole 15 and a via hole 16 are formed by performing a plating process and a patterning (wiring) process on each of the openings H1 and H2, which are formed in the fourth process, and on each surface layer of the first base material 11 and the second base material 13. As a result, a circuit wiring pattern is formed which is used in an electronic device using the printed-wiring board 10.

In this manner, the printed-wiring board 10 as shown in FIG. 1 is realized which includes the circuit wiring pattern used in the electronic device.

FIGS. 7 through 11 show an exemplary manufacturing process of a printed-wiring board with a built-in component according to a second embodiment of the invention.

In a first process shown in FIG. 7, the circuit component 20, which serves as the built-in component, is covered with the stress relaxation material 40. In the first process, a method can be adopted which performs solder precoating on terminals of the circuit component 20, and dips the circuit component 20 in a bath of the stress relaxation material 40, thereby causing the stress relaxation material 40 to adhere to the circuit component 20.

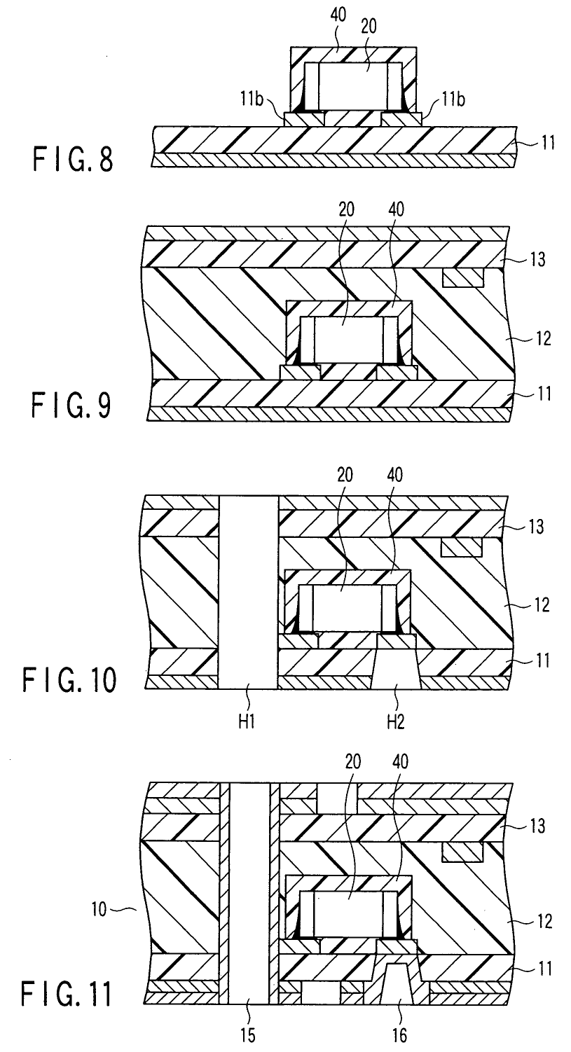

In a second process shown in FIG. 8, the circuit component 20 covered with the stress relaxation material 40 is placed on the component mounting surface of the first base material 11. Terminals 20A and 20A of the circuit component 20 are solder bonded to the electrodes 11b and 11b, thereby mounting the circuit component 20 on the component mounting portion of the component mounting surface of the first base material 11. By this component mounting process, the space between the component mounting surface and the lower surface of the circuit component 20 is filled with the stress relaxation material 40 adhering to the lower surface of the circuit component 20. Thereafter, the stress relaxation material 40 is cured by performing a heating process thereon.

As for the first and second processes, it is also possible to use another method. For example, in the first process, the circuit component 20 may be covered with the stress relaxation material 40 except for the lower surface of the circuit component 20, and, in the second process, the space between the component mounting surface and the lower surface of the circuit component 20 may be filled with the stress relaxation material 40.

In a third process shown in FIG. 9, the stress relaxation material 40 covering the circuit component 20 is covered with the resin material 12 so as to form an insulating layer on the first base material 11. Further, the second base material 13, which serves as another member, is stacked on the first base material 11 by interposing the insulating layer between the first base material 11 and the second base material 13.

In a fourth process shown in FIG. 10, openings (holes) for forming a through-hole, a via hole, etc. are formed in the printed-wiring board 10 in which each of the above-mentioned members are integrated. The openings are formed by drilling or laser processing. The conductive patterns of the layers are electrically connected via the openings. The opening formed in the fourth process and serving as a through-hole is indicated by H1, and the opening formed in the fourth process and serving as a via hole is indicated by H2.

In a fifth process shown in FIG. 11, the through-hole 15 and the via hole 16 are formed by performing a plating process and a patterning (wiring) process on each of the openings H1 and H2, which are formed in the fourth process, and on each surface layer of the first base material 11 and the second base material 13. As a result, a circuit wiring pattern is formed which is used in an electronic device using the printed-wiring board 10.

In this manner, it is possible to manufacture the printed-wiring board 10 according to the first embodiment as shown in FIG. 1, which includes the circuit wiring pattern used in the electronic device.

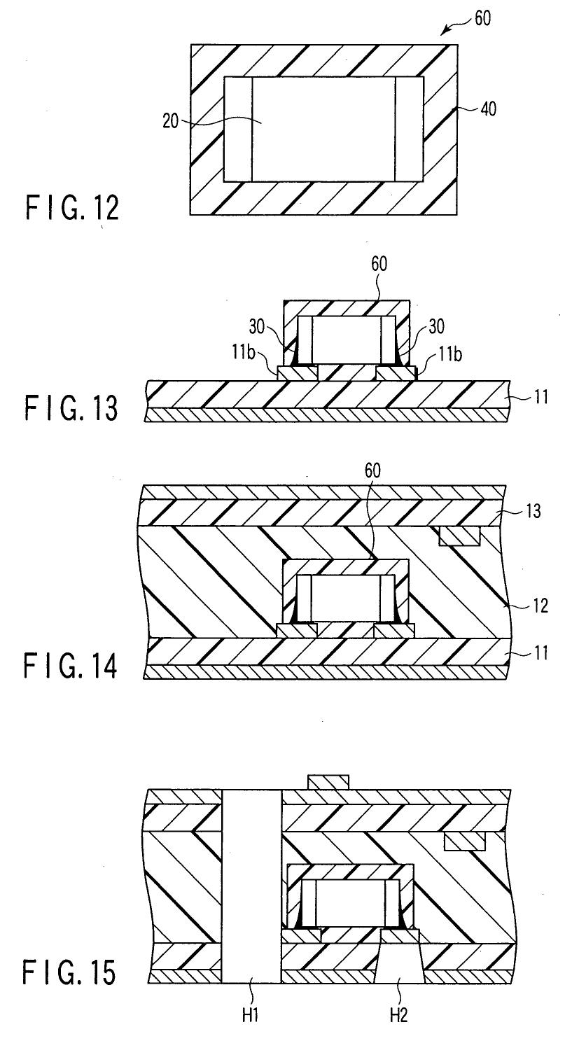

FIGS. 12 through 16 show an exemplary manufacturing process of a printed-wiring board with a built-in component according to a third embodiment of the invention.

In a first process shown in FIG. 12, a built-in component 60 with a stress relaxation material is prepared by causing a stress relaxation material (corresponding to the stress relaxation material 40 in the first and second embodiments) to adhere to a circuit component (corresponding to the circuit component 20 in the first and second embodiments) in advance, and semi-curing the stress relaxation material (for example, the stress relaxation material is semi-cured to B-stage). The built-in component 60 with the stress relaxation material is taken out by, for example, a mounter one by one at the time of component mounting.

In a second process shown in FIG. 13, the built-in component 60 is placed on the first base material 11 by, for example, the mounter. Terminals of the circuit component 20 are solder bonded to the electrodes 11b and 11b, so as to mount the circuit component (the built-in component 60 with the stress relaxation material) on the component mounting portion of the component mounting surface of the first base material 11. In the second process, it is possible to use the method of providing in advance the semi-cured stress relaxation material in the space between the component mounting surface and the lower surface of the circuit component, or the method of filling the space under the lower surface of the circuit component with the stress relaxation material after the circuit component is mounted on the first base material 11. Further, in the second process, a heating process is performed on the built-in component 60 with the stress relaxation material mounted on the component mounting portion of the first base material 11, so as to cure the stress relaxation material adhering to the circuit component.

In a third process shown in FIG. 14, the built-in component 60 is covered with the resin material 12 so as to form an insulating layer on the first base material 11. Further, the second base material 13, which serves as another member, is stacked on the first base material 11 by interposing the insulating layer between the first base material 11 and the second base material 13.

In a fourth process shown in FIG. 15, openings (holes) for forming a through-hole, a via hole, etc. are formed in the printed-wiring board in which each of the above-mentioned members are integrated. The openings are formed by drilling or laser processing. The conductive patterns of the layers are electrically connected via the openings. The opening formed in the fourth process and serving as a through-hole is indicated by H1, and the opening formed in the fourth process and serving as a via hole is indicated by H2.

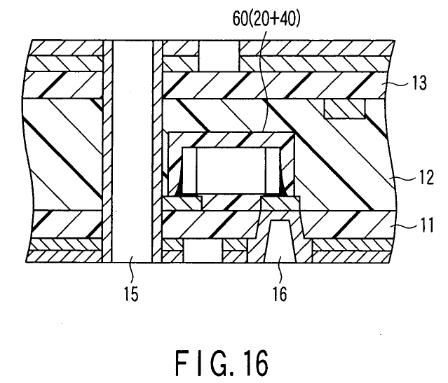

In a fifth process shown in FIG. 16, the through-hole 15 and the via hole 16 are formed by performing a plating process and a patterning (wiring) process on each of the openings H1 and H2, which are formed in the fourth process, and on each surface layer of the first base material 11 and the second base material 13. As a result, a circuit wiring pattern is formed which is used in an electronic device using the printed-wiring board.

In this manner, it is possible to manufacture the printed-wiring board which includes the circuit wiring pattern used in the electronic device, and is similar to the printed-wiring board 10 according to the first embodiment shown in FIG. 1.

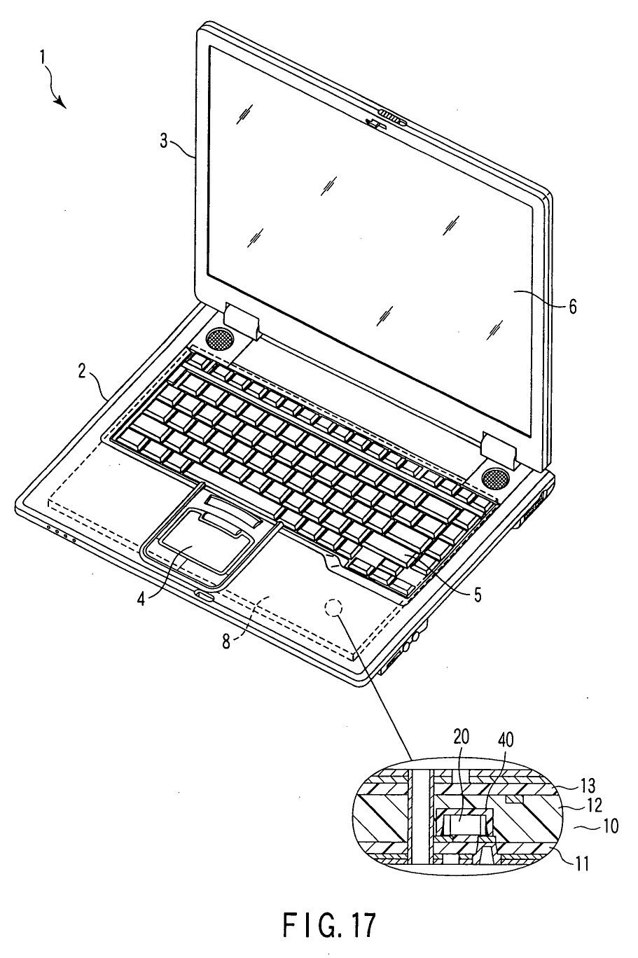

FIG. 17 shows an exemplary structure of an electronic device including the printed-wiring board with the built-in component which is manufactured in accordance with one of the above-mentioned embodiments. FIG. 17 shows an exemplary case where the printed-wiring board 10 according to the first embodiment is applied to a small electronic device such as a portable computer.

In FIG. 17, a display housing 3 is rotatably attached to a main body 2 of a portable computer 1 via a hinge mechanism. The main body 2 is provided with operation units such as a pointing device 4, a keyboard 5, etc. The display housing 3 is provided with a display device 6 such as an LCD, etc.

In addition, the main body 2 includes a printed-circuit board (motherboard) 8 incorporating therein a control circuit which controls the display device 6 and the operation units such as the pointing device 4, the keyboard 5, etc. The printed-circuit board 8 is realized by the printed-wiring board 10 with the built-in component shown in FIG. 1.

In the printed-wiring board 10 used in the printed-circuit board 8, the circuit component 20 mounted on the component mounting surface of the fist base material 11 and serving as the built-in component is covered with the stress relaxation material 40. The stress relaxation material 40 provided (inserted) between the circuit component 20 and the insulating layer formed by the resin material 12 functions to relax the external stress and the stress due to expansion/contraction on the circuit component 20.

As mentioned above, the structure is adopted where the circuit component 20 covered with the stress relaxation material 40 is mounted in the printed-wiring board. Hence, even if the external stress or the stress due to thermal expansion is exerted on the printed-circuit board 8, it is possible to relax such stress on the circuit component 20, which is incorporated in the printed circuit board 8, by the stress relaxation material 40, and to protect the circuit component 20 from the stress. Further, the space between the circuit component 20 and the component mounting surface of the first base material 11 is filled with the stress relaxation material 40. Hence, it is possible to prevent formation of voids under the circuit component 20. Accordingly, it is possible to provide a more reliable electronic device which operates stably.

The invention is not limited to the above-mentioned embodiments. For example, the invention can be realized in a multi-layer printed-wiring board with a built-in component in which a plurality of core members are stacked. Additionally, the structure of the built-in component is not limited to those described in the above-mentioned embodiments. For example, the invention can be applied to a printed-wiring board with a built-in component incorporating therein an active element or a passive element having three or more terminals.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A printed-wiring board with a built-in component, comprising:
a first base material including a component mounting surface;
a circuit component mounted on the component mounting surface of the first base material;
a stress relaxation material covering the circuit component; and
a second base material stacked on the first base material by interposing, between the first base material and the second base material, an insulating layer covering the stress relaxation material.

2. The printed-wiring board according to claim 1, wherein the stress relaxation material includes a thermo-setting resin material which relaxes a thermal stress between the insulating layer and the circuit component.

3. The printed-wiring board according to claim 2, wherein the first base material and the second base material form a multi-layer printed-wiring board, and each of the first base material and the second base material includes a wiring layer.

4. The printed-wiring board according to claim 3, wherein each of the first base material and the second base material is formed by using a sheet prepreg, and includes a wiring layer formed on an inner-layer side surface and an outer layer side surface thereof.

5. The printed-wiring board according to claim 2, wherein a space formed between the component mounting surface and a lower surface of the circuit component mounted on the component mounting surface is filled with the stress relaxation material.

6. The printed-wiring board according to claim 1, wherein the stress relaxation material includes a thermo-setting resin material which relaxes a bending stress between the insulating layer and the circuit component.

7. The printed-wiring board according to claim 6, wherein the first base material and the second base material form a multi-layer printed-wiring board, and each of the first base material and the second base material includes a wiring layer.

8. The printed-wiring board according to claim 7, wherein each of the first base material and the second base material is formed by using a sheet prepreg, and includes a wiring layer formed on an inner-layer side surface and an outer layer side surface thereof.

9. The printed-wiring board according to claim 6, wherein a space formed between the component mounting surface and a lower surface of the circuit component mounted on the component mounting surface is filled with the stress relaxation material.

10. The printed-wiring board according to claim 1, wherein a space formed between the component mounting surface and a lower surface of the circuit component mounted on the component mounting surface is filled with the stress relaxation material.

11. The printed-wiring board according to claim 1, wherein the circuit component includes a chip component including a pair of electrodes to be connected to a conductive pattern formed on the component mounting surface.

12. A manufacturing method of a printed-wiring board with a built-in component, comprising:
mounting a circuit component on a component mounting surface of a first base material;
covering the circuit component mounted on the component mounting surface of the first base material with a stress relaxation material;
forming an insulating layer which covers the stress relaxation material on the first base material; and
stacking, on the first base material, a second base material including a conductive pattern by interposing the insulating layer between the first base material and the second base material.

13. The manufacturing method according to claim 12, wherein covering the circuit component with the stress relaxation material includes:
filling, with the stress relaxation material, a space formed between the component mounting surface and a lower surface of the circuit component mounted on the component mounting surface.

14. An electronic device, comprising:
a main body; and
a circuit board provided in the main body, wherein the circuit board includes:
a first base material including a component mounting surface;
a circuit component mounted on the component mounting surface of the first base material;
a stress relaxation material covering the circuit component; and
a second base material including a conductive pattern and stacked on the first base material by interposing, between the first base material and the second base material, an insulating layer which covers the stress relaxation material.
